(19) United States
(12) Patent Application Publication
(10) Pub. No.: US 2025/0275388 A1
(43) Pub. Date: Aug. 28, 2025

(54) DISPLAY SUBSTRATE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yanhong DING, Beijing (CN); Zhu WANG, Beijing (CN); Bin LIU, Beijing (CN); Gansong YANG, Beijing (CN); Zhenglong YAN, Beijing (CN); Danyang MA, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/705,002

(22) PCT Filed: Mar. 23, 2023
(86) PCT No.: PCT/CN2023/083397

§ 371 Date: Apr. 26, 2024

(30) Foreign Application Priority Data
Mar. 30, 2022 (CN) 202210334033.4

(51) Int. Cl. H10K 59/131; H10K 59/121; H10K 59/35

(52) U.S. Cl. CPC H10K 59/131; H10K 59/121; H10K 59/353

(57) ABSTRACT

A display substrate is provided, the display substrate has a display region and includes a base substrate, sub-pixels, data lines, and first signal lines; each of at least part of the sub-pixels includes a pixel driving circuit and a light-emitting device; the data lines are in a first metal layer, the first signal lines are in a second metal layer; in a first display region, a plurality of first signal lines extend in a first direction, the first display region includes first compensation patterns, the first electrode is on a side of the first signal lines and the first compensation patterns away from the base substrate, an orthographic projection of at least one first compensation pattern on the base substrate at least partially overlaps with an orthographic projection of the first electrode of a light-emitting device of at least one sub-pixel on the base substrate.

### CROSS-REFERENCE TO RELATED APPLICATION

This application claims priority to Chinese Patent Application No. 202210334033.4, filed on Mar. 30, 2022, the disclosure of which is hereby incorporated by reference in its entirety as part of this application for all purposes.

### TECHNICAL FIELD

Embodiments of the present disclosure relate to a display substrate.

### BACKGROUND

OLED (Organic Light-Emitting Diode) display devices have a series of advantages such as self-luminescence, high contrast, high definition, wide viewing angle, low power consumption, fast response speed, and low manufacturing cost, have been one of the important development directions of a new generation of display devices, and thus have received increasing attention.

For OLED display devices, the width of the bezel is an important factor affecting the visual effect, and in general, the narrower the bezel, the better the visual effect.

### SUMMARY

At least one embodiment of the present disclosure provides a display substrate, the display substrate has a display region, the display region comprises a base substrate, a plurality of sub-pixels, a plurality of data lines, and a plurality of first signal lines, the plurality of sub-pixels are on the base substrate, each of at least part of the plurality of sub-pixels comprises a pixel driving circuit and a light-emitting device, the light-emitting device comprises a first electrode electrically connected to the pixel driving circuit, the plurality of data lines are on the base substrate and in a first metal layer, and the plurality of first signal lines are on the base substrate and in a second metal layer, the second metal layer is on a side of the first metal layer away from the base substrate, at least one of the plurality of first signal lines is electrically connected to at least one of the plurality of data lines through a first via; the display region comprises a first display region, in the first display region, the plurality of first signal lines extend in a first direction, the first display region comprises a plurality of first compensation patterns, in the first display region, first electrodes of light-emitting devices of the plurality of sub-pixels are on a side of the plurality of first signal lines and the plurality of first compensation patterns away from the base substrate, an orthographic projection of at least one of the plurality of first compensation patterns on the base substrate at least partially overlaps with an orthographic projection of the first electrode of the light-emitting device of at least one of the plurality of sub-pixels on the base substrate.

For example, in the display substrate provided by at least one embodiment of the present disclosure, the plurality of first compensation patterns are in the second metal layer.

For example, in the display substrate provided by at least one embodiment of the present disclosure, the display region further comprises a second display region, in the second display region, the plurality of first signal lines extend in a second direction, the second display region comprises a second compensation pattern, in the second display region, first electrodes of light-emitting devices of the plurality of sub-pixels are on a side of the plurality of first signal lines and the plurality of second compensation patterns away from the base substrate, an orthographic projection of at least one of the plurality of second compensation patterns on the base substrate at least partially overlaps with an orthographic projection of the first electrode of the light-emitting device of at least one of the plurality of sub-pixels on the base substrate; the first direction is different from the second direction.

For example, in the display substrate provided by at least one embodiment of the present disclosure, the first direction is perpendicular to the second direction.

For example, in the display substrate provided by at least one embodiment of the present disclosure, the plurality of first signal lines are electrically connected to the plurality of data lines through a plurality of first vias, respectively, the plurality of first vias are in the second display region and arranged in a straight line, the straight line intersects the first direction and the second direction.

For example, in the display substrate provided by at least one embodiment of the present disclosure, in the second display region, the plurality of first signal lines extend in the second direction to an edge of the display region.

For example, in the display substrate provided by at least one embodiment of the present disclosure, in the second display region, the plurality of first signal lines extend in the second direction to an edge of the display region and are disconnected on a side of the plurality of first vias close to the edge.

For example, in the display substrate provided by at least one embodiment of the present disclosure, portions of the plurality of first signal lines disconnected on the side of the plurality of first vias close to the edge are electrically connected with the plurality of data lines, respectively.

For example, in the display substrate provided by at least one embodiment of the present disclosure, the pixel driving circuit and the first electrode are electrically connected through a second via, in a direction perpendicular to the base substrate, the second via does not overlap with the first via.

For example, in the display substrate provided by at least one embodiment of the present disclosure, the plurality of first compensation patterns and the plurality of second compensation patterns are respectively in a shape of Chinese character “-”, a shape of Chinese character “ [symbol] ”, a shape of Chinese character “ [symbol] ”, a shape of Chinese character “ [symbol] ”, a shape of a ring or a shape of a block.

For example, in the display substrate provided by at least one embodiment of the present disclosure, the plurality of second compensation patterns are in the second metal layer.

For example, in the display substrate provided by at least one embodiment of the present disclosure, in the first display region, the plurality of first compensation patterns comprise first compensation patterns electrically connected with the plurality of first signal lines, respectively, and respectively in a shape of Chinese character “-” extending in the second direction.

For example, in the display substrate provided by at least one embodiment of the present disclosure, the plurality of sub-pixels comprise red sub-pixels, green sub-pixels, and blue sub-pixels, light-emitting devices of the red sub-pixels and the blue sub-pixels are in a same row, and light-emitting devices of the green sub-pixels are in a same row, and rows where the light-emitting devices of the red sub-pixels and the blue sub-pixels are located and rows where the light-emitting devices of the green sub-pixels are located are alternately arranged; the light-emitting devices of the red sub-pixels and the blue sub-pixels are in a same column, the light-emitting devices of the green sub-pixels are in a same column, and columns where the light-emitting devices of the red sub-pixels and the blue sub-pixels are located and columns where the light-emitting devices of the green sub-pixels are located are alternately arranged.

For example, in the display substrate provided by at least one embodiment of the present disclosure, in the first display region and in the direction perpendicular to the base substrate, the first signal line at least partially overlaps with the light-emitting device of the green sub-pixel, and the first signal line does not overlap with the light-emitting devices of the red sub-pixel and the blue sub-pixel.

For example, in the display substrate provided by at least one embodiment of the present disclosure, in the first display region and in the direction perpendicular to the base substrate, a first electrode of a light-emitting device of the green sub-pixel at least partially overlaps the first compensation pattern in the shape of Chinese character “-”.

For example, in the display substrate provided by at least one embodiment of the present disclosure, the plurality of first compensation patterns further comprise a first compensation pattern in a shape of Chinese character “ [symbol] ” on at least one side of the plurality of first signal lines, the first compensation pattern in the shape of Chinese character “-” comprises two portions respectively extending along the first direction and the second direction.

For example, in the display substrate provided by at least one embodiment of the present disclosure, the first compensation pattern in the shape of Chinese character “ [symbol] ” is spaced apart from the plurality of first signal lines.

For example, in the display substrate provided by at least one embodiment of the present disclosure, in the direction perpendicular to the base substrate, the first electrodes of the light-emitting devices of the red sub-pixel and the blue sub-pixel respectively overlap with one first compensation pattern in the shape of Chinese character “ [symbol] ”.

For example, in the display substrate provided by at least one embodiment of the present disclosure, in the second display region, the plurality of second compensation patterns comprise a second compensation pattern in a shape of Chinese character “ [symbol] ” on at least one side of the plurality of first signal lines, the second compensation pattern in the shape of Chinese character “ [symbol] ” comprises two portions respectively extending along the first direction and the second direction; in the direction perpendicular to the base substrate, first electrodes of light-emitting devices of the green sub-pixel, the red sub-pixel and the blue sub-pixel respectively overlap with one second compensation pattern in the shape of Chinese character “ [symbol] ”.

For example, in the display substrate provided by at least one embodiment of the present disclosure, the light-emitting device further comprises a light-emitting material layer on a side of the first electrode away from the base substrate and a second electrode on a side of the light-emitting material layer away from the base substrate; the display substrate further has a peripheral region surrounding the display region, the display substrate further comprises a first power signal line configured to provide a first power signal to second electrodes of the plurality of sub-pixels, and the first power signal line is electrically connected, in the peripheral region, to the second electrodes of the plurality of sub-pixels.

For example, in the display substrate provided by at least one embodiment of the present disclosure, in the second display region, the second compensation pattern in the shape of Chinese character “ [symbol] ” is electrically connected with the first power signal line.

For example, the display substrate provided by at least one embodiment of the present disclosure further comprises a second power signal line, wherein the plurality of first signal lines are on a side of the second power signal line away from the base substrate, the second compensation pattern in the shape of Chinese character “ [symbol] ” is electrically connected to the second power signal line.

For example, in the display substrate provided by at least one embodiment of the present disclosure, the display region further comprises a third display region, the third display region comprises a metal pattern, first electrodes of light-emitting devices of the plurality of sub-pixels are on a side of the metal pattern away from the base substrate, the metal pattern comprises a plurality of metal lines extending at least along the first direction and the second direction and crossing with each other; or, the metal pattern comprises a plurality of block patterns respectively overlapping with the first electrodes of the light-emitting devices of at least part of the plurality of sub-pixels.

For example, in the display substrate provided by at least one embodiment of the present disclosure, the metal pattern is in a same layer as the plurality of first signal lines.

For example, in the display substrate provided by at least one embodiment of the present disclosure, the second display region comprises a first sub-display region and a second sub-display region, the first display region is between the first sub-display region and the second sub-display region.

For example, in the display substrate provided by at least one embodiment of the present disclosure, the third display region is on one side of the first display region and the second display region.

### BRIEF DESCRIPTION OF DRAWINGS

In order to clearly illustrate technical solutions of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a schematic plan view of a display substrate;

FIG. 2A is a schematic plan view of part of sub-pixels in a first sub-region of the display substrate in FIG. 1;

FIG. 2B is a schematic plan view of part of sub-pixels in a second sub-region of the display substrate in FIG. 1;

FIG. 3A is a schematic plan view of a display substrate provided by at least one embodiment of the present disclosure;

FIG. 3B is another schematic plan view of a display substrate provided by at least one embodiment of the present disclosure;

FIG. 4A is a schematic partial cross-sectional view of one sub-pixel of a display substrate provided by at least one embodiment of the present disclosure;

FIG. 4B is a schematic partial cross-sectional view of a connection of a first signal line and a data line in a display substrate provided by at least one embodiment of the present disclosure;

FIG. 5 is a schematic plan view of part of sub-pixels of a first display region of a display substrate provided by at least one embodiment of the present disclosure;

FIG. 6 is a schematic plan view of part of sub-pixels of a second display region of a display substrate provided by at least one embodiment of the present disclosure;

FIG. 7 is a schematic plan view of part of sub-pixels of a third display region of a display substrate provided by at least one embodiment of the present disclosure;

FIG. 8 is another schematic plan view of part of sub-pixels of a second display region or a third display region of a display substrate provided by at least one embodiment of the present disclosure;

FIG. 9 is a schematic plan view of a compensation pattern in a display substrate provided by at least one embodiment of the present disclosure;

FIG. 10 is another schematic plan view of a compensation pattern in a display substrate provided by at least one embodiment of the present disclosure; And

FIG. 11 is further another schematic plan view of a compensation pattern in a display substrate provided by at least one embodiment of the present disclosure;

FIGS. 12-14 are schematic plan views of various exemplary compensation patterns

in a display substrate provided by at least one embodiment of the present disclosure; And

FIGS. 15A-15I are schematic plan views of sequential stacking of various functional layers in a display substrate provided by at least one embodiment of the present disclosure.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

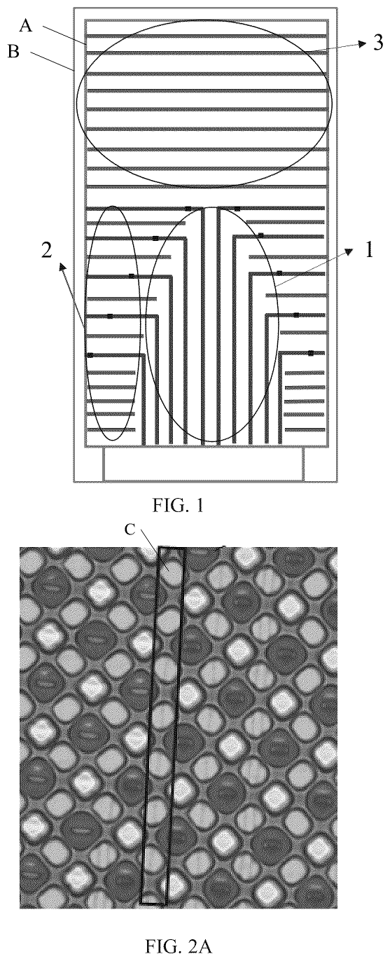

FIG. 1 shows a schematic plan view schematic diagram of a display substrate, as shown in FIG. 1, the display substrate has a display region A and a peripheral region B surrounding the display region A. In order to realize a large screen and narrow bezel design of the display substrate, part of the wiring lines in the peripheral region B can also be disposed in the display region A to reduce the area of the peripheral region B to realize a narrow bezel. For example, in some embodiments, the width of the peripheral region B can be reduced to about 1.0 mm, and therefore an extremely narrow bezel can be achieved.

For example, as shown in FIG. 1, a plurality of wiring lines extending laterally or longitudinally are provided in the display region A, e.g., wiring lines in different regions of the display region A extend in different directions.

For example, as shown in FIG. 1, the display region A includes a plurality of sub-regions, i.e., a first sub-region 1, a second sub-region 2, and a third sub-region 3. In the first sub-region 1 of the display region, the wiring line extends in the longitudinal direction, in the second sub-region 2, the wiring line extends in the lateral direction, and in the third sub-region 3, the wiring line extends in the lateral direction. Typically, light-emitting devices used for display of the display substrate are provided above these wiring lines.

The inventors of the present disclosure have found out that, when the light-emitting devices are disposed above the wiring lines, at least part of the structure of the light-emitting devices, for example, an electrode (for example, an anode) closer to the wiring lines may be uneven, and thus light emitted from the light-emitting device may be uneven under reflection of the uneven electrode, thereby affecting the display effect of the display substrate, for example, a screen Mura phenomenon may occur in the screen rest state, and traces of the wiring lines may also occur in the screen lighting state.

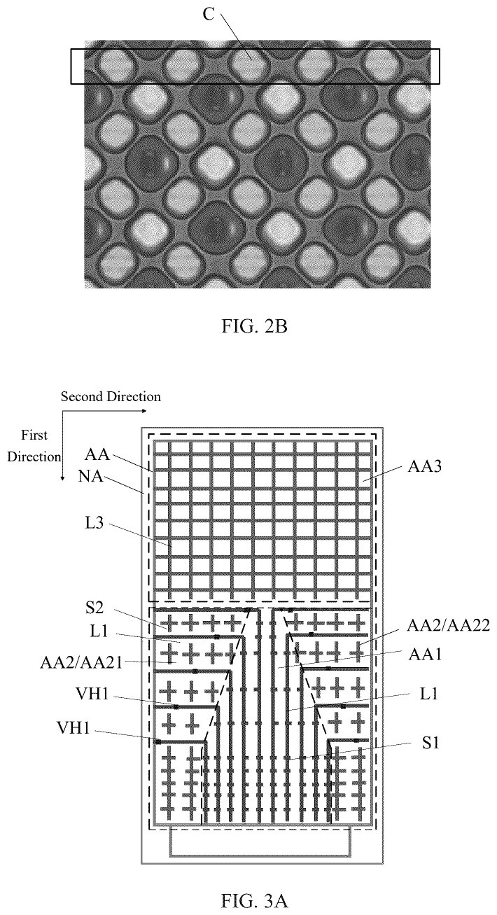

For example, FIG. 2A shows the effect of the wiring lines in the first sub-region 1 on the electrodes of the light-emitting devices, and FIG. 2B shows the effect of the wiring lines in the second sub-region 2 on the electrodes of the light-emitting devices. As shown in FIG. 2A and FIG. 2B, traces of wiring lines appear on the electrodes C of the light-emitting devices. As shown in FIG. 2A, in the first sub-region 1, the traces of the wiring lines extend longitudinally, as indicated by the rectangular frame in FIG. 2A; as shown in FIG. 2B, in the second sub-region 2, the traces of the wiring lines extend laterally, as indicated by the rectangular frame in FIG. 2B.

Through the test, the display substrate appears the Mura phenomenon in the screen rest state, and the shape of the Mura in the screen rest state perfectly matches the shape of the wiring line. When the display substrate is lit, there is a significant trace of the wiring line through and under the electrode, thereby affecting the display effect of the display substrate.

At least one embodiment of the present disclosure provides a display substrate, the display substrate has a display region, the display region includes a base substrate, a plurality of sub-pixels, a plurality of data lines and a plurality of first signal lines, the plurality of sub-pixels are disposed on the base substrate, each of at least part of the plurality of sub-pixels includes a pixel driving circuit and a light-emitting device, the light-emitting device includes a first electrode electrically connected to the pixel driving circuit; the plurality of data lines are disposed on the base substrate and disposed in a first metal layer, the plurality of first signal lines are disposed on the base substrate and disposed in a second metal layer, the second metal layer is disposed on a side of the first metal layer away from the base substrate, at least one of the plurality of first signal lines is electrically connected to at least one of the plurality of data lines through a first via; the display region includes a first display region, in the first display region, the plurality of first signal lines extend in a first direction, the first display region includes a plurality of first compensation patterns, in the first display region, first electrodes of light-emitting devices of the plurality of sub-pixels are on a side of the plurality of first signal lines and the plurality of first compensation patterns away from the base substrate, an orthographic projection of at least one of the plurality of first compensation patterns on the base substrate at least partially overlaps with an orthographic projection of the first electrode of the light-emitting device of at least one of the plurality of sub-pixels on the base substrate.

In the above display substrate provided by the embodiments of the present disclosure, the first compensation pattern can weaken or even eliminate the unevenness caused by the first signal line to the first electrode of the light-emitting device, and in turn can avoid the Mura phenomenon that may occur when the display substrate is in a screen rest state, avoid the display unevenness phenomenon when the display substrate is in a lighting state, and improve the display effect of the display substrate.

The display substrate provided by the embodiments of the present disclosure is illustrated below through several specific embodiments.

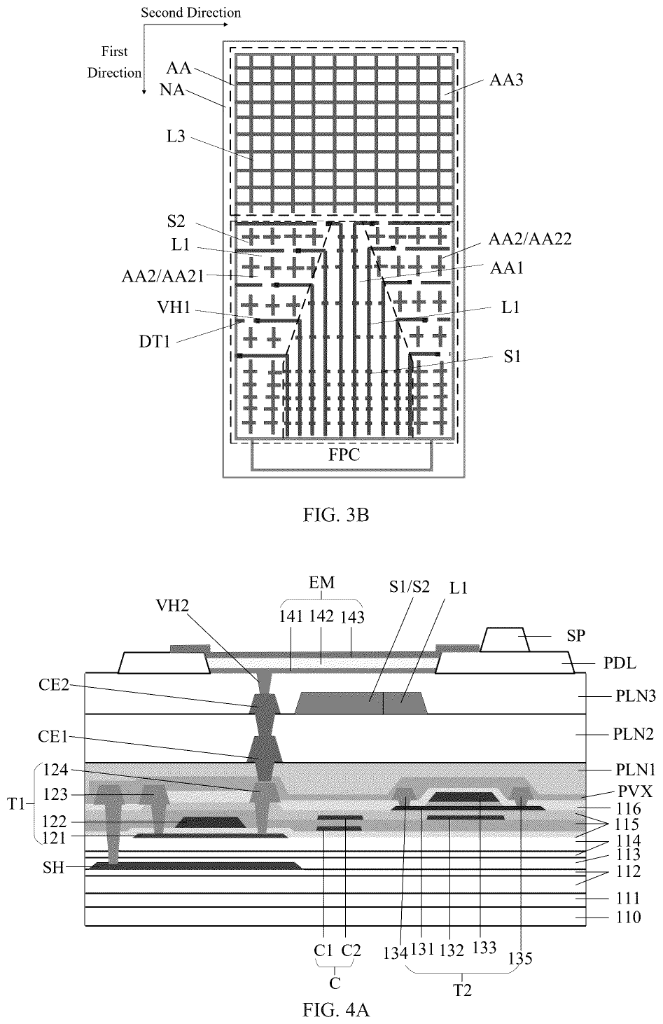

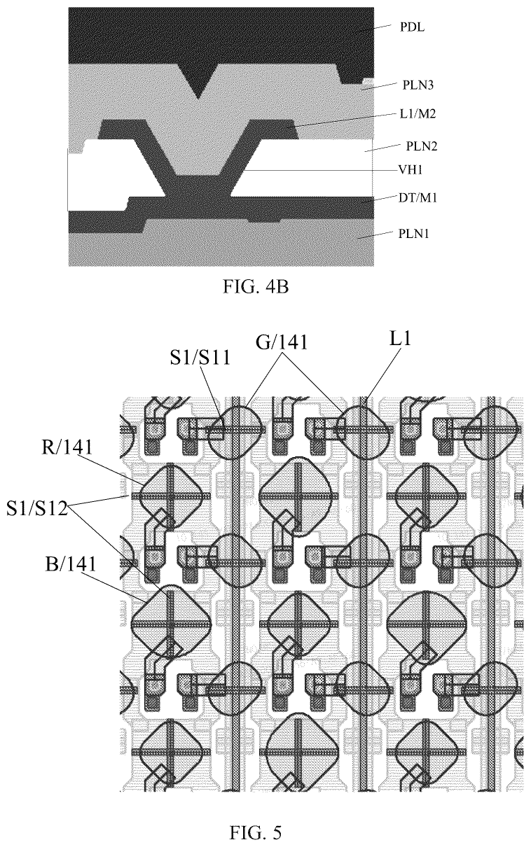

At least one embodiment of the present disclosure provides a display substrate, FIG. 3A shows a schematic plan view of the display substrate, and FIG. 4A shows a schematic partial cross-sectional view of one sub-pixel of the display substrate. As shown in FIG. 3A and FIG. 4A, the display substrate has a display region AA, and further includes a base substrate 110, a plurality of sub-pixels, and a plurality of first signal lines L1. The plurality of sub-pixels are disposed on the base substrate 110, for example, the plurality of sub-pixels are arranged in an array of a plurality of rows and a plurality of columns.

As shown in FIG. 3A and FIG. 4A, each of at least part of the plurality of sub-pixels includes a pixel driving circuit and a light-emitting device, the pixel driving circuit includes a structure such as a plurality of thin film transistors (a first thin film transistor T1 and a second thin film transistor T2 are shown in FIG. 4A as an example) and a storage capacitor C, and may be formed as, for example, a 3TIC pixel driving circuit (including three thin film transistors and one storage capacitor) or a 7T1C pixel driving circuit (including seven thin film transistors and one storage capacitor), and the specific form of the pixel driving circuit is not limited by the embodiments of the present disclosure.

The light-emitting device EM includes a first electrode 141 electrically connected to the pixel driving circuit, and further includes a second electrode 143 spaced apart from the first electrode 141, and a light-emitting material layer 142 between the first electrode 141 and the second electrode 143. The pixel driving circuit can drive the light-emitting device EM to emit light. For example, the first electrode 141 may serve as an anode of the light-emitting device EM, and the second electrode 143 may serve as a cathode of the light-emitting device EM. The light-emitting material layer 142 may include an organic light-emitting material, and different sub-pixels may include organic light-emitting materials that emit light of different colors, as desired.

As shown in FIG. 3A and FIG. 4A, the display region AA includes a first display region AA1, the first display region AA1 includes a plurality of first compensation patterns S1. For example, in the first display region AA1, the plurality of first signal lines L1 are disposed on the base substrate 110 and extend in a first direction (vertical direction in FIG. 3A), and the plurality of first compensation patterns S1 are disposed on the base substrate 110 and are respectively disposed on at least one side of the plurality of first signal lines L1 in a direction parallel to the base substrate 110, for example, on one side or both sides of the plurality of first signal lines L1.

As shown in FIG. 4A, in the first display region AA1, the first electrodes 141 of the light-emitting devices EM of the plurality of sub-pixels are located on a side of the plurality of first signal lines L1 and the plurality of first compensation patterns S1 away from the base substrate 110, an orthographic projection of at least one of the plurality of first compensation patterns S1 on the base substrate 110 at least partially overlaps with an orthographic projection of the first electrode 141 of the light-emitting device of at least one of the plurality of sub-pixels on the base substrate 110. For example, in the direction perpendicular to the base substrate 110 (the vertical direction in FIG. 4A), the plurality of first compensation patterns S1 are in one-to-one correspondence with and at least partially overlap with the first electrodes 141 of the light-emitting devices EM of at least part of the plurality of sub-pixels.

Thus, in the first display region AA1, the first compensation pattern S1 can at least partially elevate the first electrode 141, thereby weakening or even eliminating the unevenness caused by the first signal line L1 to the first electrode 141 of the light-emitting device EM, weakening or even eliminating the reflection unevenness caused by the unevenness of the first electrode 141, and in turn, it is possible to avoid the Mura phenomenon that may occur when the display substrate is in a screen rest state, avoid the display unevenness phenomenon that may occur when the display substrate is in a lighting state, and improve the display effect of the display substrate.

For example, FIG. 4B shows a schematic cross-sectional view of the display substrate at a first via, as shown in FIG. 4B, the display substrate further includes a plurality of data lines DT, the plurality of data lines DT are disposed on the base substrate and disposed in the first metal layer M1, the plurality of first signal lines L1 are disposed on the base substrate and disposed in the second metal layer M2, the second metal layer M2 is disposed on a side of the first metal layer M1 away from the base substrate, at least one of the plurality of first signal lines L1 is electrically connected with at least one of the plurality of data lines DT through the first via VH1, e.g., the plurality of first signal lines L1 are electrically connected with the plurality of data lines DT through a plurality of first vias VH1, respectively. Therefore, the plurality of first signal lines L1 can transmit data signals to the plurality of data lines DT, and provide data signals to the plurality of sub-pixels.

For example, the plurality of first compensation patterns S1 are disposed in the second metal layer M2, thereby being disposed in the same layer as the plurality of first signal lines L1, so the plurality of first compensation patterns S1 and the plurality of first signal lines L1 can be formed of the same material layer by the same patterning process in the manufacturing process, and therefore the manufacturing process of the display substrate can be simplified.

For example, in some embodiments, as shown in FIG. 3A and FIG. 4A, the display region AA further includes a second display region AA2, the second display region AA2 includes a plurality of second compensation patterns S2, e.g., in the second display region AA2, the plurality of first signal lines L1 are disposed on the base substrate 110 and extend in the second direction (horizontal direction in FIG. 3A), and the plurality of second compensation patterns S2 are disposed on the base substrate 110 and respectively disposed on at least one side of the plurality of first signal lines L1 in a direction parallel to the base substrate 110, e.g., on one side or both sides of the plurality of first signal lines L1.

For example, in the second display region AA2, the first electrodes 141 of the light-emitting devices EM of the plurality of sub-pixels are located on a side of the plurality of first signal lines L1 and the plurality of second compensation patterns S2 away from the base substrate 110, an orthographic projection of at least one second compensation pattern S2 of the plurality of second compensation patterns on the base substrate 110 at least partially overlaps with an orthographic projection of the first electrode 141 of the light-emitting device of at least one of the plurality of sub-pixels on the base substrate 110. For example, in the direction perpendicular to the base substrate 110, the plurality of second compensation patterns S2 are in one-to-one correspondence and at least partially overlapped with the first electrodes 141 of the light-emitting devices EM of at least part of the plurality of sub-pixels.

Thus, in the second display region AA2, the second compensation pattern S2 can at least partially elevate the first electrode 141, thereby reducing or even eliminating the unevenness caused by the first signal line L1 to the first electrode 141 of the light-emitting device EM, reducing or even eliminating the reflection unevenness caused by the unevenness of the first electrode 141, and further, it is possible to avoid the Mura phenomenon that may occur when the display substrate is in a screen rest state, avoid the display unevenness phenomenon that may occur when the display substrate is in a lighting state, and improve the display effect of the display substrate.

For example, the above-mentioned first direction is different from the second direction. For example, in some embodiments, the first direction is perpendicular to the second direction. For example, in the example shown in FIG. 3A, the first direction is a vertical direction, i.e., a column direction of the sub-pixels, and the second direction is a horizontal direction, i.e., a row direction of the sub-pixels. In other examples, the first direction may also be the row direction of the sub-pixels and the second direction is the column direction of the sub-pixels.

For example, in some embodiments, the plurality of first compensation patterns S1 and the plurality of second compensation patterns S2 may be in a shape of Chinese character “-”, a shape of Chinese character “ [symbol] ”, a shape of Chinese character “ [symbol] ”, a shape of Chinese character “ [symbol] ”, a shape of a ring, or a shape of a block, respectively. The shapes of the plurality of first compensation patterns S1 and the plurality of second compensation patterns S2 may be the same or different.

For example, in some embodiments, the plurality of second compensation patterns S2 are also disposed in the second metal layer M2, that is, the plurality of second compensation patterns S2 are disposed in the same layer as the plurality of first compensation patterns S1 and the first signal lines L1, to simplify the manufacturing process of the display substrate, and fully achieve the compensation effect of the compensation patterns on the wiring lines.

It should be noted that, in the embodiments of the present disclosure, the “in a/the same layer” means that two (or more) functional layers or structural layers are formed of the same layer and the same material in the hierarchical structure of the display substrate, i.e., in the manufacturing process, the two functional layers or structural layers can be formed of the same material layer, and the desired patterns and structures can be formed by the same patterning process.

For example, as shown in FIG. 3A, the plurality of first vias VH1 are located in the second display region AA2 and are arranged in a straight line that intersects the first direction and the second direction, for example, the straight line is shown as an oblique line in the figure.

For example, as shown in FIG. 3A, in some embodiments, in the second display region AA2, the plurality of first signal lines L1 extend in the second direction to the edge of the display region AA (shown as the edges on the left and right sides in the figure). Thus, the first signal lines L1 can have better etching uniformity in the manufacturing process, avoiding non-uniformity of the manufacturing process caused by different lengths of the first signal lines L1, and improving the yield of the display substrate. For example, the first signal line L1 may acquire a data signal from the driver circuit FPC provided below the display region AA, and then the data signal is transmitted in the first direction in the first display region AA1, then transmitted in the second direction in the second display region AA2, and then transmitted to the data line DT located in the first metal layer M1, and then transmitted by the data line DT to each sub-pixel.

For example, in other embodiments, as shown in FIG. 3B, in the second display region AA2, the plurality of first signal lines L1 extend to an edge of the display region in the second direction, and are disconnected on a side of the plurality of first vias VH1 close to the edge of the display region. In this case, the first signal line L1 can still acquire the data signal from the driver circuit FPC provided below the display region AA, and then transmit the data signal to the data line DT located in the first metal layer M1, and then the data line DT transmits the data signal to each sub-pixel.

For example, in some embodiments, a portion DT1 of the signal line that is disconnected and close to the edge of the display region AA may be floating; alternatively, in some embodiments, the portions DT1 of the plurality of first signal lines L1 disconnected on the side of the plurality of vias VH1 close to the edge may be electrically connected with the plurality of data lines DT, respectively, and therefore these signal line portions DT1 are respectively connected in parallel with the plurality of data lines DT, which can reduce the voltage drop of the data lines DT.

For example, in some embodiments, the pixel driving circuit and the first electrode 141 are electrically connected through a second via VH2, in the direction perpendicular to the base substrate, the second via VH2 does not overlap with the plurality of first vias VH1. That is, the second via VH2 and the first via VH1 adopt an avoiding design, to prevent the display substrate from being poorly manufactured or the like in the vicinity of the respective vias.

For example, FIG. 5 shows a schematic plan view of part of sub-pixels of the first display region. As shown in FIG. 5, in some embodiments, the plurality of sub-pixels include red sub-pixels R, green sub-pixels G, and blue sub-pixels B, one red sub-pixel R, two green sub-pixels G, and one blue sub-pixel B constitute one pixel unit, and a plurality of pixel units are arranged in an array on the base substrate 110. For example, in other embodiments, one red sub-pixel R, one green sub-pixel G and one blue sub-pixel B may also constitute one pixel unit, the embodiments of the present disclosure do not limit the specific composition of the pixel unit.

For example, as shown in FIG. 5, in some embodiments, the light-emitting devices of the red sub-pixels R and the blue sub-pixels B are located in the same row, the light-emitting devices of the green sub-pixels G are located in the same row, and the rows where the light-emitting devices of the red sub-pixels R and the blue sub-pixels B are located and the rows where the light-emitting devices of the green sub-pixels G are located are alternately arranged. For example, the light-emitting devices of the red sub-pixels R and the blue sub-pixels B are located in the same column, the light-emitting devices of the green sub-pixels G are located in the same column, and the columns where the light-emitting devices of the red sub-pixels R and the blue sub-pixels B are located and the columns where the light-emitting devices of the green sub-pixels G are located are alternately arranged.

For example, as shown in FIG. 5, in some embodiments, in the first display region AA1, in the direction perpendicular to the base substrate, the first signal line L1 at least partially overlaps with the light-emitting device of the green sub-pixel G, and the first signal line L1 does not overlap with the light-emitting devices of the red sub-pixel R and the blue sub-pixel B.

For example, as shown in FIG. 5, in some embodiments, the plurality of first compensation patterns S1 includes a first compensation pattern S11, in the shape of Chinese character “-”, electrically connected with the plurality of first signal lines L1, respectively, and extending along the second direction. The compensation pattern S11 in the shape of Chinese character “-” passes through the first signal line L1, thereby including two portions respectively located on both sides of the first signal line L1.

For example, in some embodiments, in the first display region AA1, in the direction perpendicular to the base substrate 110, the first electrode 141 of the light-emitting device of the green sub-pixel G overlaps with the first signal line L1, in this case, the first compensation pattern S11 in the shape of Chinese character “-” can at least partially elevate the first electrode of the light-emitting device of the green sub-pixel G, that is, the first compensation pattern S11 in the shape of Chinese character “-” is disposed below the first electrode of the light-emitting device of the green sub-pixel G, so that in the direction perpendicular to the base substrate 110, the first electrode of the light-emitting device of the green sub-pixel G at least partially overlaps with the first compensation pattern S11 in the shape of Chinese character “-”.

For example, in some embodiments, the plurality of first compensation patterns S1 further include a first compensation pattern S12 in the shape of Chinese character “ [symbol] ” respectively disposed on at least one side of the plurality of first signal lines L1, the first compensation pattern S12 in the shape of Chinese character “ [symbol] ” includes two portions respectively extending along the first direction and the second direction. For example, the first compensation pattern S12 in the shape of Chinese character “ [symbol] ” is spaced apart from the plurality of first signal lines L1, that is, the first compensation pattern S12 in the shape of Chinese character “ [symbol] ” is not electrically connected to the plurality of first signal lines L1

For example, in some embodiments, as shown in FIG. 5, in the direction perpendicular to the base substrate 110, the first signal line L1 does not overlap with the first electrodes 141 of the light-emitting devices of the red sub-pixel R and the blue sub-pixel B, and thus, the first compensation pattern S12 in the shape of Chinese character “ [symbol] ” can elevate the first electrodes 141 of the light-emitting devices of the red sub-pixel R and the blue sub-pixel B, that is, the first electrodes 141 of the light-emitting devices of the red sub-pixel R and the blue sub-pixel B respectively overlap with one first compensation pattern S12 in the shape of Chinese character “ [symbol] ”.

Therefore, in the first display region 11, the first signal line L1 and the first compensation pattern S11 in the shape of Chinese character “-” that are overlapped with the first electrode of the light emitting device of the green sub-pixel G, as a whole, are also in a shape of Chinese character “ [symbol] ”, therefore, the shapes of the compensation patterns or lines overlapped with the first electrodes 141 of the light-emitting devices of the green sub-pixel G, the red sub-pixel R and the blue sub-pixel B are substantially consistent, so that the surfaces where the light-emitting devices of the sub-pixels of different colors are located have substantially the same flatness, the first electrodes of the light-emitting devices of the sub-pixels of different colors have a uniform light reflectivity, and therefore the light-emitting uniformity of the light-emitting devices of the sub-pixels of different colors can be improved, in turn, the display uniformity of the display substrate can be improved, and the display effect of the display substrate is improved.

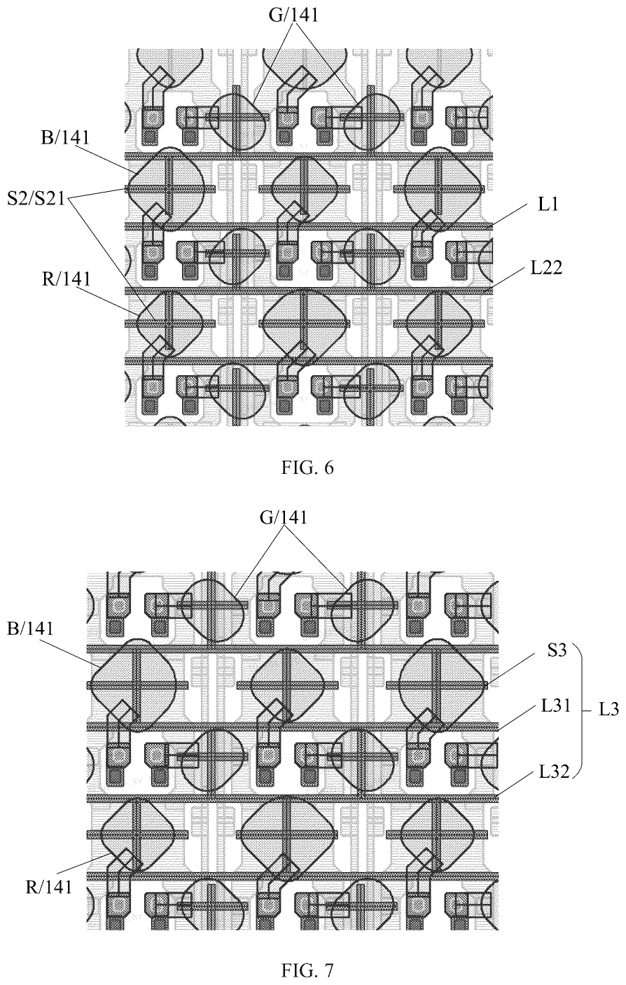

For example, FIG. 6 shows a schematic plan view of part of sub-pixels of the second display region. As shown in FIG. 6, in some embodiments, in the second display region AA2, the plurality of second compensation patterns S2 includes a second compensation pattern S21 in the shape of Chinese character “ [symbol] ” respectively disposed on at least one side of the plurality of first signal lines L1, the second compensation pattern S21 in the shape of Chinese character “ [symbol] ” includes two portions respectively extending in the first direction and the second direction. For example, in the direction perpendicular to the base substrate 110, the first electrodes 141 of the light-emitting devices of the green sub-pixel G, the red sub-pixel R, and the blue sub-pixel B respectively overlap with one second compensation pattern S21 in the shape of Chinese character “ [symbol] ”.

Thus, in the second display region AA2, the surfaces where the light-emitting devices of the sub-pixels of different colors are located have substantially the same flatness, and the surfaces also have substantially the same flatness as the surfaces where the light-emitting devices of the sub-pixels of different colors are located in the first display region AA1, the first electrodes of the light-emitting devices of the sub-pixels of different colors have uniform light reflectivity, and therefore the display uniformity of the plurality of display regions can be improved.

For example, as illustrated in FIG. 4A, the light-emitting material layer 142 of the light-emitting device EM is disposed on a side of the first electrode 141 away from the base substrate 110, and the second electrode 143 is disposed on a side of the light-emitting material layer 142 away from the base substrate 110. For example, the display substrate further has a peripheral region NA surrounding the display region AA, the display substrate further includes a first power signal line L22, the first power signal line L22 is configured to provide a first power signal to the second electrodes 143 of the plurality of sub-pixels, e.g., the first power signal is a low-level power signal.

For example, the first power signal line L22 is electrically connected to the second electrodes 143 of the plurality of sub-pixels in the peripheral region NA, to provide the low-level power signal to the second electrodes 143 of the plurality of sub-pixels; the setting of the first power signal line L22 can effectively reduce the power drop, thereby reducing the power consumption of the display substrate.

For example, in some embodiments, in the second display region AA2, the second compensation pattern S21 in the shape of Chinese character “ [symbol] ” is electrically connected with the first power signal line L22, but is not electrically connected with the first signal line L1 providing the data signal. For example, the second compensation pattern S21 in the shape of Chinese character “ [symbol] ” is connected as a whole with the first power signal line L22, but is spaced apart from the first signal line L1 that provides the data signal.

For example, as shown in FIG. 3A, the display region AA further includes a third display region AA3, the third display region AA3 includes a metal pattern L3, the first electrodes 141 of the light-emitting devices EM of the plurality of sub-pixels are disposed on a side of the metal pattern L3 away from the base substrate 110, the metal pattern L3 includes a plurality of metal lines extending at least in the first direction and the second direction and crossing with each other (the case shown in FIG. 3A), for example, the plurality of metal lines form a grid shape; alternatively, in other embodiments, the metal pattern L3 includes a plurality of block patterns respectively overlapped with the first electrodes 131 of the light-emitting devices EM of at least part of the plurality of sub-pixels (described in detail later), and in this case, the plurality of block patterns are in one-to-one correspondence with and overlapped with the first electrodes 131 of the light-emitting devices EM of the at least part of the sub-pixels.

For example, in some embodiments, the metal pattern L3 may be a dummy metal pattern, not electrically connected to any circuit; alternatively, in other embodiments, a portion of the metal pattern L3 is used as a wiring line for transmitting an electrical signal, such as a wiring line for transmitting a low-level power signal, and the like, and the other portion is a compensation pattern.

For example, FIG. 7 shows a schematic plan view of part of sub-pixels of the third display region. As shown in FIG. 7, in some embodiments, the metal pattern L3 includes a plurality of wiring lines L31 and a plurality of wiring lines L32, for example, the plurality of wiring lines L31 are electrically connected with data lines providing data signals to the plurality of sub-pixels, and the plurality of wiring lines L32 are electrically connected with first power signal lines providing first power signals, for example, low-level power signals, to the second electrodes 143 of the plurality of sub-pixels, for example, the metal pattern L3 further includes a third compensation pattern S3 electrically connected with the wiring line L31 and the wiring line L32, respectively. In this case, the entirety of the data line L31, the first power signal line L32 and the third compensation pattern S3 is in an interlaced mesh metal pattern.

For example, as shown in FIG. 7, each third compensation pattern S3 is in the shape of Chinese character “ [symbol] ”, and the first electrodes 141 of the light-emitting devices of the green sub-pixel G, the red sub-pixel R, and the blue sub-pixel B are respectively overlapped with one third compensation pattern S3 in the shape of Chinese character “ [symbol] ” in the direction perpendicular to the base substrate 110.

Therefore, in the third display region AA3, the surfaces where the light-emitting devices of the sub-pixels of different colors are located have substantially the same flatness, and the surfaces have substantially the same flatness as the surfaces where the light-emitting devices of the sub-pixels of different colors are located in the first display region AA1 and the second display region AA2, the first electrodes of the light-emitting devices of the sub-pixels of different colors have a uniform light reflectivity, and therefore the display uniformity of the plurality of display regions can be improved.

For example, in other embodiments, FIG. 8 shows another schematic plan view of part of sub-pixels in the second display region AA2 or the third display region AA3 in the display substrate. As shown in FIG. 8, in the second display region AA2 or the third display region AA3, the display substrate may further include a second power signal line L4, with reference to FIG. 4A, the second power signal line L4 is disposed in the same layer as the first connection electrode CE1 (described in detail later) or the source-drain electrodes 123 and 124, for example. For example, the second power signal line is a power line that provides a high-level power signal.

For example, in the second display region AA2, the plurality of first signal lines L1 are disposed on a side of the second power signal line L4 away from the base substrate 110, in this case, the second compensation pattern S21 in the shape of Chinese character “ [symbol] ” can be electrically connected with the second power signal line L4 without being electrically connected with the plurality of first signal lines L1.

For example, referring to FIG. 4A and FIG. 8, in a case where the second power signal line L4 is disposed in the same layer as the first connection electrode CE1, the second planarization layer PLN2 has a via V therein, the second compensation pattern S21 in the shape of Chinese character “ [symbol] ” is electrically connected with the second power signal line L4 through the via V; alternatively, in a case that the second power signal line L4 is disposed in the same layer as the source-drain electrodes 123 and 124, the first planarization layer PLN1 and the second planarization layer PLN2 have a via V therein, and the second compensation pattern S21 in the shape of Chinese character “ [symbol] ” is electrically connected with the second power signal line L4 through the via V.

For example, in the third display region AA3, the metal pattern L3 is disposed on a side of the second power signal line L4 away from the base substrate 110, in this case, the metal pattern L3 can be electrically connected with the second power signal line L4. For example, the planarization layer between the metal pattern L3 and the second power signal line L4 may have a via V, the metal pattern L3 and the second power signal line L4 are electrically connected through the via V.

For example, in some embodiments, the metal pattern L3 is disposed in the same layer as the plurality of first signal lines L1, that is, in the second metal layer M2, and therefore the manufacturing process of the display substrate can be simplified.

For example, in some embodiments, as shown in FIG. 3A, the second display region AA2 may include a first sub-display region AA21 and a second sub-display region AA22, the first display region AA1 is between the first sub-display region AA21 and the second sub-display region AA22. For example, the first sub-display region AA21 and the second sub-display region AA22 have substantially the same structure, and are substantially symmetrically disposed.

For example, as shown in FIG. 3A, the third display region AA3 is disposed on one side of the first display region AA1 and the second display region AA2, shown in FIG. 3A as being on the upper side of the first display region AA1 and the second display region AA3.

For example, in the embodiments of FIGS. 5-7, the first compensation patterns S1 and the second compensation patterns S2 are respectively described as being in the shape of Chinese character “-” or in the shape of Chinese character “ [symbol] ”, as an example, and in other embodiments, the first compensation patterns S1 and the second compensation patterns S2 may also in a shape of Chinese character “ [symbol] ”, a shape of Chinese character “ [symbol] ”, a shape of a block, or other suitable shapes. For example, the block shape may be rectangular, square, or a shape substantially same as the shape of the first electrode 141, or the like, thereby providing a substantially flat surface for the arrangement of the first electrode 141. For example, the specific shapes of the plurality of block compensation patterns for sub-pixels of different colors may be the same or different.

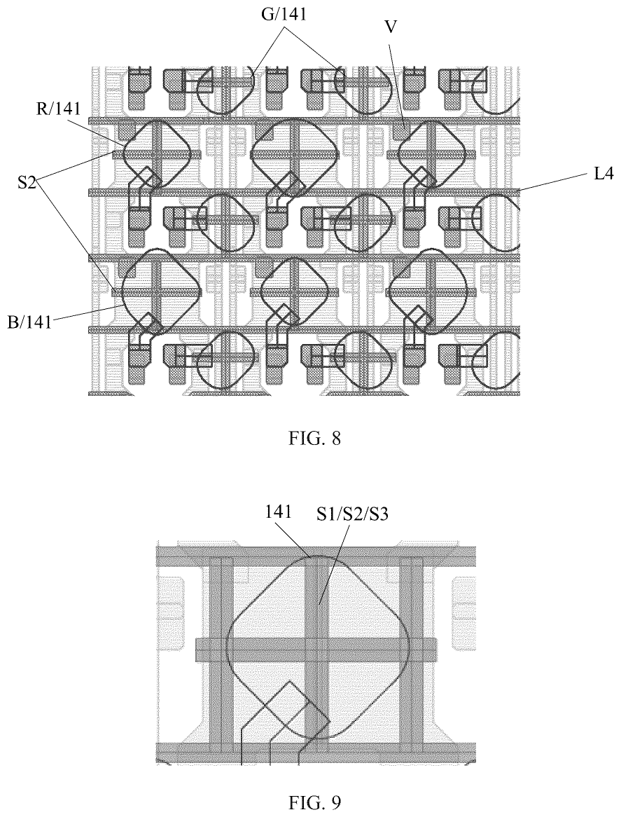

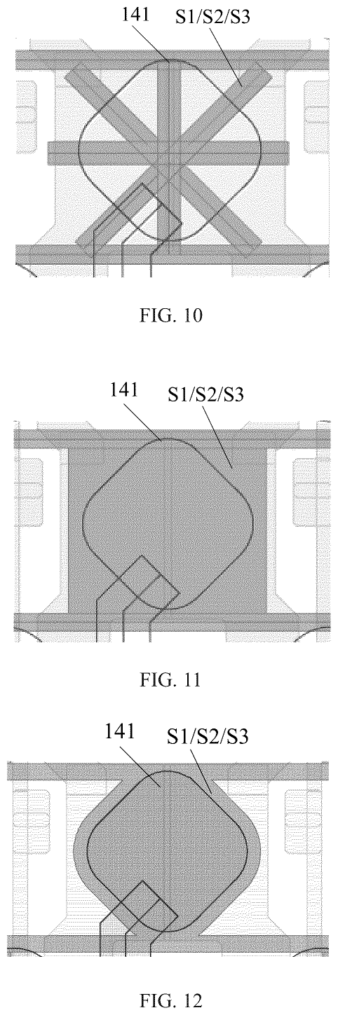

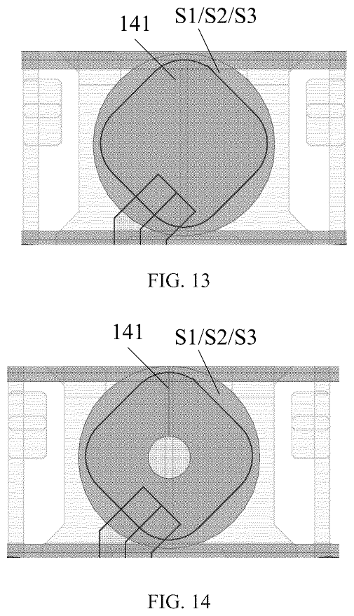

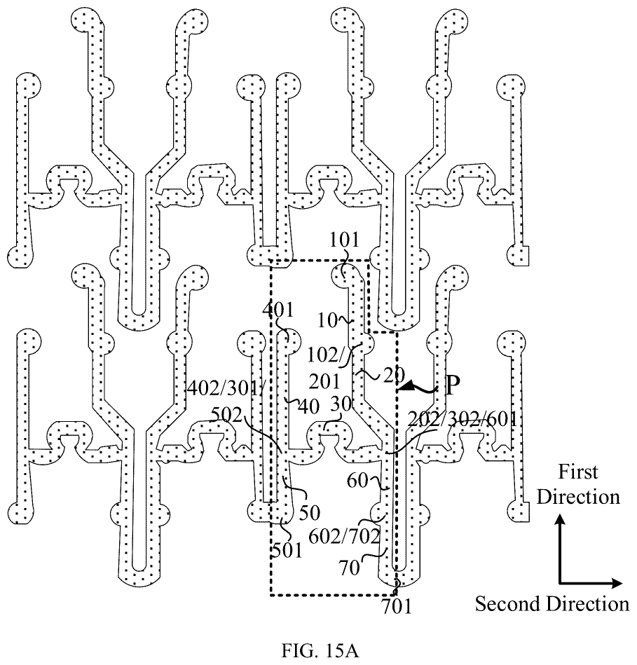

For example, FIG. 9 illustrates a case where the first compensation pattern S1, the second compensation pattern S2, or the third compensation pattern S3 is in the shape of Chinese character “ [symbol] ”, FIG. 10 illustrates a case where the first compensation pattern S1, the second compensation pattern S2, or the third compensation pattern S3 is in the shape of Chinese character “ [symbol] <”, FIGS. 11, 12, and 13 illustrate a case where the first compensation pattern S1, the second compensation pattern S2, or the third compensation pattern S3 is in the block shape, and FIG. 14 illustrates a case where the first compensation pattern S1, the second compensation pattern S2, or the third compensation pattern S3 is in a ring shape. For example, in FIG. 11, the first compensation pattern S1, the second compensation pattern S2, or the third compensation pattern S3 is in a rectangular block shape; in FIG. 12, the first compensation pattern S1, the second compensation pattern S2, or the third compensation pattern S3 is in a block shape substantially same as the shape of the first electrode 141; in FIG. 13, the first compensation pattern S1, the second compensation pattern S2, or the third compensation pattern S3 is in a circular block shape. In FIG. 14, the first compensation pattern S1, the second compensation pattern S2, or the third compensation pattern S3 is in a circular ring shape, and may also be in a rectangular ring shape or the like in other embodiments.

These compensation patterns provided under the first electrode can all realize at least partially elevating the first electrode, thereby reducing or even eliminating the unevenness caused by the first signal line L1 to the first electrode 141 of the light-emitting device EM, reducing or even eliminating the light reflection unevenness caused by the unevenness of the first electrode 141, and improving the display effect of the display substrate. For example, the shapes of the plurality of first compensation patterns S1 may be the same or different, the shapes of the plurality of second compensation patterns S2 may be the same or different, and the shapes of the plurality of third compensation patterns S3 may be the same or different.

For example, in some embodiments, as shown in FIG. 4A, the first thin film transistor T1 and the second thin film transistor T2 included in the pixel driving circuit may have different structures. For example, the first thin film transistor T1 includes an active layer 121, a gate electrode 122, and source-drain electrodes 123 and 124. The display substrate further includes a first connection electrode CE1 located on a side of the source-drain electrodes 123 and 124 away from the base substrate 110 and a second connection electrode CE2 located on a side of the first connection electrode CE1 away from the base substrate 110, the source-drain electrode 124 is electrically connected with the first electrode 141 of the light-emitting device EM through the first connection electrode CE1 and the second connection electrode CE2. For example, the second thin film transistor T2 includes an active layer 131, a first gate electrode 132, a second gate electrode 133 and source-drain electrodes 134 and 135, the second thin film transistor T2 is a double-gate thin film transistor, the first gate electrode 132 and the second gate electrode 133 are disposed at opposite sides of the active layer 131 in the direction perpendicular to the base substrate 110.

For example, in some embodiments, the plurality of first signal lines L1 and the plurality of first compensation patterns S1, the plurality of second compensation patterns S2, and the metal pattern L3 are disposed in the same layer as the second connection electrode CE2, that is, in the second metal layer M2.

For example, the storage capacitor C included in the pixel driving circuit includes a first capacitor electrode C1 and a second capacitor electrode C2. For example, the first capacitor electrode C1 is disposed in the same layer as the gate electrode 122 of the first thin film transistor T1, and the second capacitor electrode C2 is disposed in the same layer as the first gate electrode 132 of the second thin film transistor T2, to simplify the manufacturing process of the display substrate.

For example, in some embodiments, the display substrate further includes a light-shielding layer SH disposed between the base substrate 110 and the active layer 121, the light-shielding layer SH can achieve a shielding effect for the active layer 121, thereby preventing light incident from the base substrate 110 from irradiating to the active layer 121 to affect the normal operation of the first thin film transistor T1.

For example, the display substrate further includes a barrier layer 111 and a buffer layer 112 disposed on the base substrate 110, the barrier layer 111 and the buffer layer 112 can prevent impurities in the base substrate 110 from entering into the plurality of functional layers of the display substrate, thereby playing a protective role.

For example, in the embodiments of the present disclosure, the base substrate 110 may adopt a rigid substrate such as a glass substrate, a quartz substrate, or the like, or a flexible substrate such as a polyimide substrate, or the like. The barrier layer 111 and the buffer layer 112 may adopt an inorganic insulating material such as silicon oxide, silicon nitride, or silicon nitride oxide. For example, the buffer layer 112 may have a plurality of sub-layers, and the materials of the plurality of sub-layers may be the same or different. For example, in one example, the material of one sub-layer is silicon oxide, the material of another sub-layer is silicon nitride, etc.

For example, the light-shielding layer SH may adopt a metal material such as copper (Cu), aluminum (Al), titanium (Ti), or molybdenum (Mo), or an alloy material thereof. An insulating layer 113 and a buffer layer 114 may be further provided on the light-shielding layer SH, and the insulating layer 113 and the buffer layer 114 may also adopt an inorganic insulating material such as silicon oxide, silicon nitride, or silicon nitride oxide.

For example, the active layer 121 may adopt a silicon-based semiconductor material, such as amorphous silicon a-Si, polycrystalline silicon p-Si, or the like. The active layer 131 may also adopt a metal oxide semiconductor material, such as IGZO, ZnO, AZO, IZTO, or the like. The gate electrode 122, the first gate electrode 132, the second gate electrode 133, the first capacitor electrode C1, and the second capacitor electrode C2 may adopt a metal material such as copper (Cu), aluminum (Al), titanium (Ti), molybdenum (Mo), or an alloy material thereof, for example, may be formed as a single-layer metal structure or a multi-layer metal structure, for example, a multi-layer metal of titanium/aluminum/titanium. The source-drain electrodes 123 and 124 and the source-drain electrodes 134 and 135 may adopt a metal material such as copper (Cu), aluminum (Al), titanium (Ti), molybdenum (Mo), or an alloy material thereof, for example, may be formed as a single-layer metal structure or a multi-layer metal structure, for example, a multi-layer metal structure of titanium/aluminum/titanium.

For example, the first connection electrode CE1 and the second connection electrode CE2 as well as the wiring lines and the compensation patterns may adopt a metal material such as copper (Cu), aluminum (Al), titanium (Ti), molybdenum (Mo), or an alloy material thereof, and may be formed, for example, as a single-layer metal structure or a structure, such as a multi-layer metal structure of multi-layer metal titanium/aluminum/titanium.

For example, a gate insulating layer 115 may be provided between the active layer and the gate electrode and between the first capacitor electrode and the second capacitor electrode, and the gate insulating layer 115 may adopt an inorganic insulating material such as silicon oxide, silicon nitride, or silicon nitride oxide. For example, an interlayer insulating layer 116 may be provided between the second gate electrode 133 and the source-drain electrodes 134 and 135, and the interlayer insulating layer 116 may adopt an inorganic insulating material such as silicon oxide, silicon nitride, or silicon nitride oxide.

For example, a passivation layer PVX may be disposed on the source-drain electrodes 123 and 124 and the source-drain electrodes 134 and 135, a first planarization layer PLN1 may be disposed on the passivation layer PVX, a second planarization layer PLN2 may be disposed on the first connection electrode CE1, and a third planarization layer PLN3 may be disposed on the second connection electrode CE2. For example, the passivation layer PVX may adopt an inorganic insulating material such as silicon oxide, silicon nitride, or silicon nitride oxide. The first planarization layer PLN1, the second planarization layer PLN2, and the third planarization layer PLN3 may adopt an organic insulating material such as polyimide, resin, or the like.

For example, the first electrode 141 includes a material having a high work function to be used as an anode, for example, the first electrode 141 has an ITO/Ag/ITO stacked structure; the second electrode 143 includes material having a low work function to be used as a cathode, for example, the second electrode 143 adopt a semi-transmissive metal or metal alloy material, such as an Ag/Mg alloy material. The light-emitting material layer 142 may include, for example, an auxiliary light-emitting layer in addition to the organic light-emitting material, such as a hole transport layer, a hole injection layer, an electron transport layer, an electron injection layer, and the like.

For example, as illustrated in FIG. 4A, the display substrate further includes a pixel definition layer PDL disposed on the first electrode 141 and a spacer layer SP disposed on the pixel definition layer PDL. The pixel definition layer PDL includes a plurality of sub-pixel openings for defining light-emitting regions of the sub-pixels. The spacer layer SP is used to define an encapsulation space. For example, the pixel definition layer PDL and the spacer layer SP may adopt an organic insulating material such as polyimide or resin.

For example, the display substrate may further include an encapsulation layer (not shown) disposed on the spacer layer SP, and the encapsulation layer may be a composite encapsulation layer including a stack of a plurality of organic encapsulation layers and inorganic encapsulation layers. For example, the inorganic encapsulation layer may adopt an inorganic insulating material such as silicon oxide, silicon nitride, or silicon oxynitride; and the organic encapsulation layer may adopt an organic insulating material such as polyimide, resin, or the like.

For example, the display substrate may further include other structures besides the above-mentioned structures, specifically reference may be made to the related art, which is not repeated here.

In addition, it should be illustrated that the embodiments of the present disclosure do not limit the material of each functional layer, and the material of each functional layer is not limited to the above examples. In the embodiments of the present disclosure, each thin film transistor may be a P-type thin film transistor or an N-type thin film transistor, the structure may be a bottom-gate type, a top-gate type or a double-gate type, the structures shown in the drawings are merely exemplary, and the embodiments of the present disclosure do not limit the specific form of each thin film transistor.

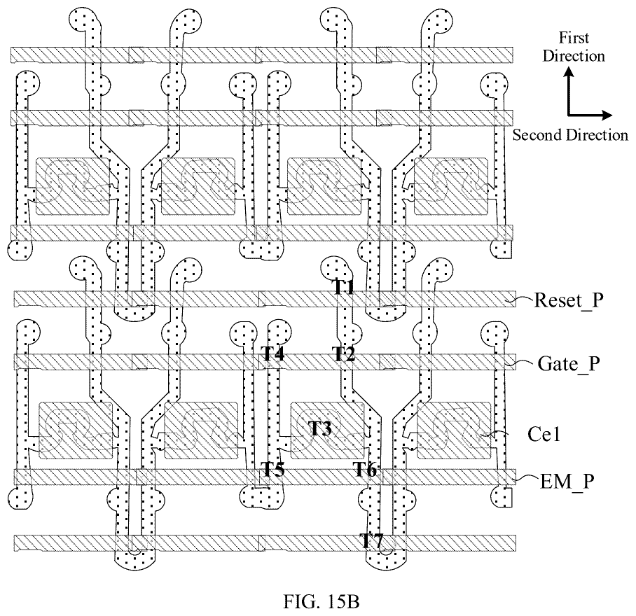

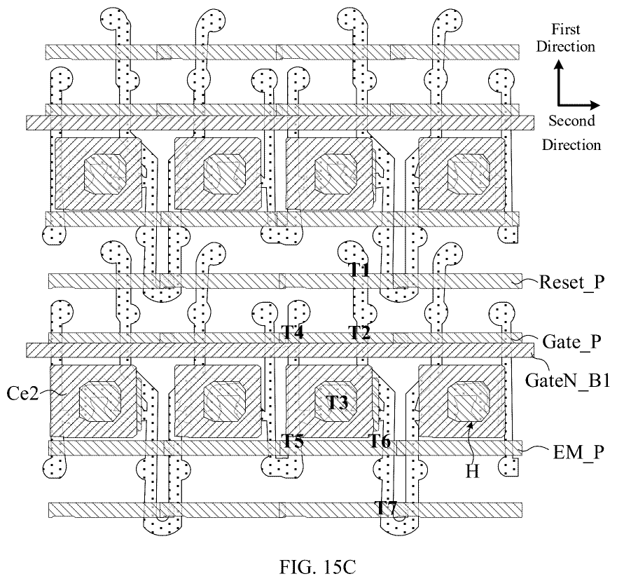

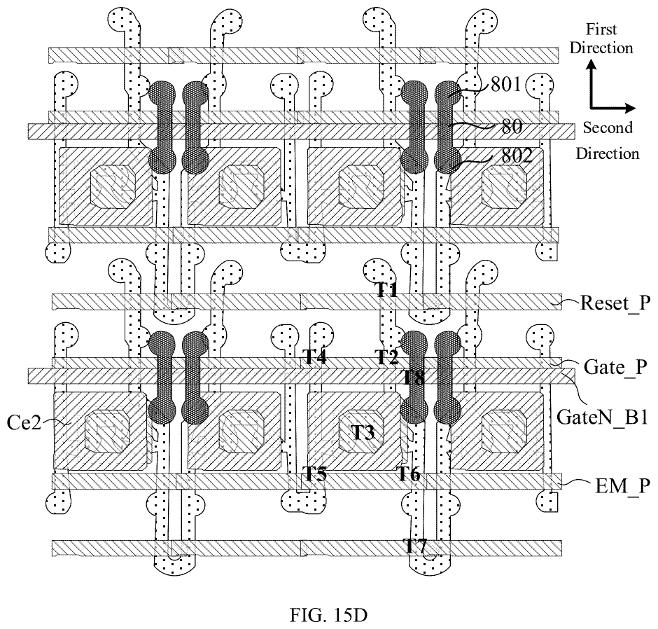

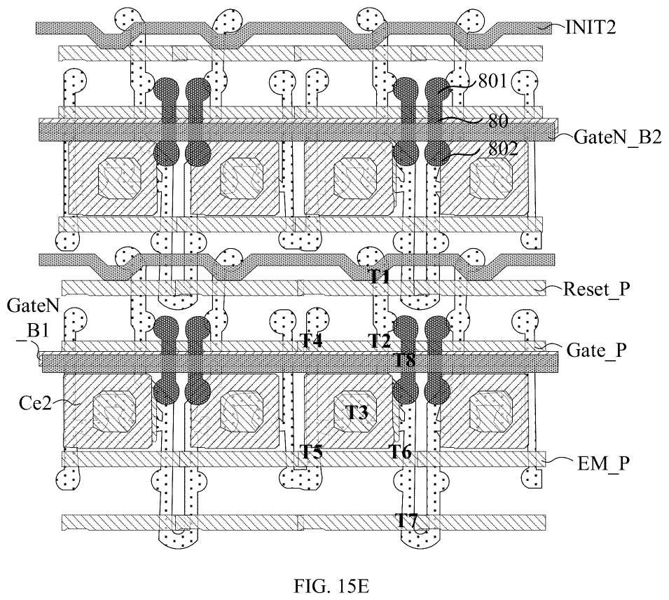

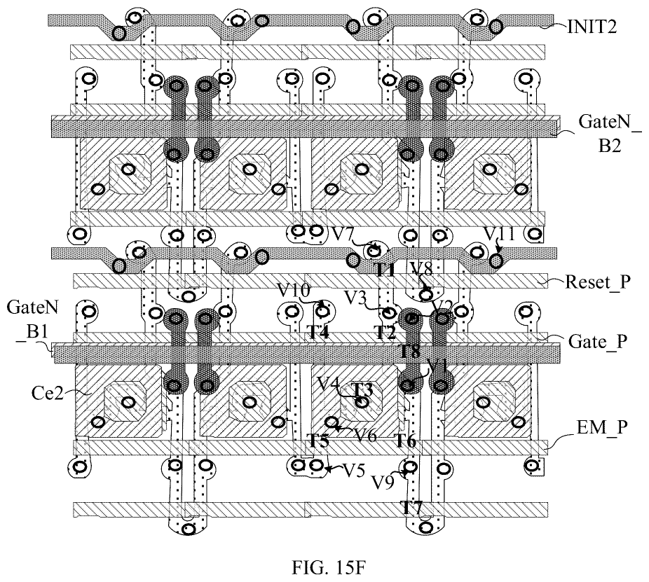

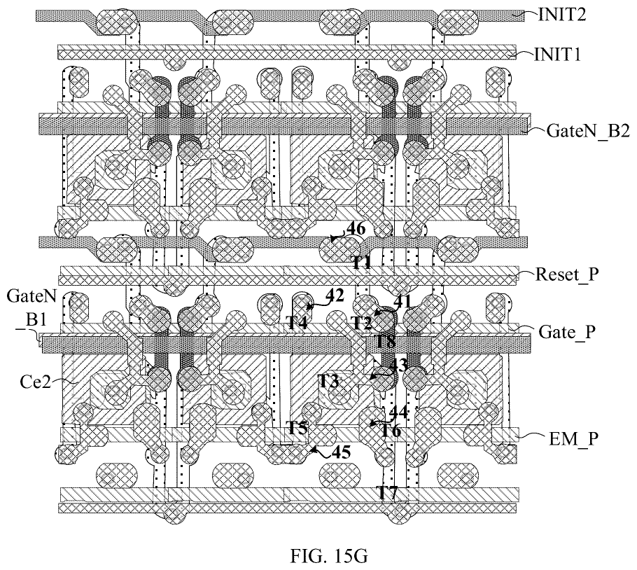

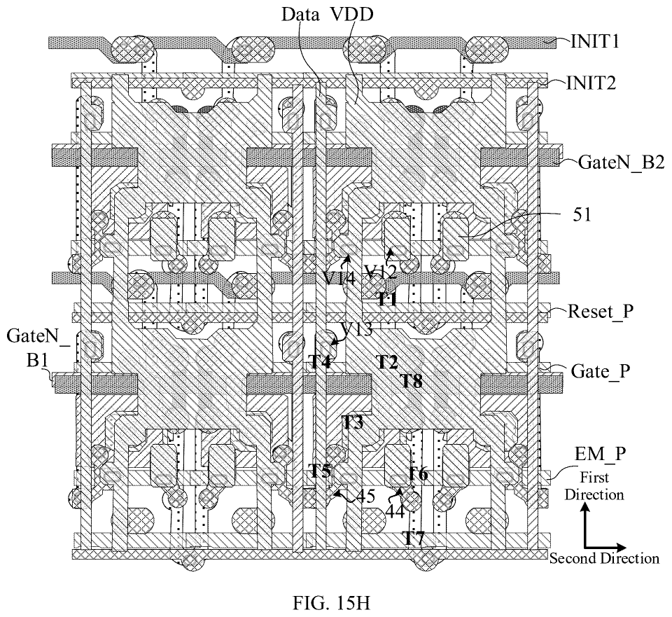

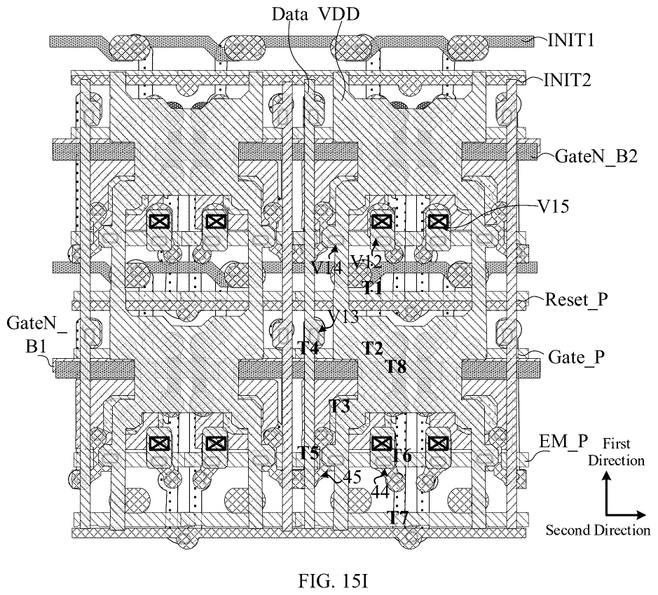

For example, FIGS. 15A-15I show schematic plan views in which respective functional layers of the display panel, provided by at least one embodiment of the present disclosure, are sequentially stacked, in this display panel, the pixel driving circuit adopts an 8T1C structure, i.e., includes eight thin film transistors T1-T8 and one storage capacitor.

FIG. 15A shows a first semiconductor layer pattern. The first semiconductor layer pattern may adopt a silicon material, and the silicon material includes amorphous silicon and polysilicon. As shown in FIG. 15A, the first semiconductor layer pattern may include a first active layer 10 of the first transistor T1, a second active layer 20 of the second transistor T2, a third active layer 30 of the third transistor T3, a fourth active layer 40 of the fourth transistor T4, a fifth active layer 50 of the fifth transistor T5, a sixth active layer 60 of the sixth transistor T6, and a seventh active layer 70 of the seventh transistor T7. The first active layer 10, the second active layer 20, the third active layer 30, the fourth active layer 40, the fifth active layer 50, the sixth active layer 60, and the seventh active layer 70 are mutually connected as an integral structure.

In some exemplary implementations, the third active layer 30 may have a shape of Chinese character “ [symbol] ”, and the first active layer 10, the second active layer 20, the fourth active layer 40, the fifth active layer 50, the sixth active layer 60, and the seventh active layer 70 may have a shape of “1”.

In some exemplary implementations, the active layer of each transistor may include a first region, a second region, and a channel region between the first region and the second region. In some exemplary implementations, the second region 102 of the first active layer 10 also serves as the first region 201 of the second active layer 20, i.e., the second region 102 of the first active layer 10 and the first region 201 of the second active layer 20 are connected with each other. The first region 301 of the third active layer 30 also serves as the second region 402 of the fourth active layer 40 and the second region 502 of the fifth active layer 50, i.e., the first region 301 of the third active layer 30, the second region 402 of the fourth active layer 40 and the second region 502 of the fifth active layer 50 are connected with each other. The second region 302 of the third active layer 30 also serves as the first region 601 of the sixth active layer 60 and the second region 202 of the second active layer 20, i.e., the second region 302 of the third active layer 30, the first region 601 of the sixth active layer 60 and the second region 202 of the second active layer 20 are connected with each other. The second region 602 of the sixth active layer 60 also serves as the second region 702 of the seventh active layer 70, i.e., the second region 602 of the sixth active layer 60 and the second region 702 of the seventh active layer 70 are connected with each other. The first region 101 of the first active layer 10, the first region 401 of the fourth active layer 40, the first region 501 of the fifth active layer 50, and the first region 701 of the seventh active layer 70 are provided separately.

In some exemplary implementations, in the first direction, the first semiconductor layers of any two adjacent columns of sub-pixels are mirror symmetric structures.

In some exemplary implementations, the channel region of the third active layer 30 extends along a row direction, and the channel regions of the first active layer 10, the second active layer 20, the fourth active layer 40, the fifth active layer 50, the sixth active layer 60, and the seventh active layer 70 extend along a column direction.

In some exemplary implementations, the first semiconductor layer may adopt polysilicon (p-Si), i.e., the first transistor, the second transistor, the third transistor, the fourth transistor, the fifth transistor, the sixth transistor, and the seventh transistor may all be LTPS thin film transistors.

For example, FIG. 15B shows a schematic plan view of a first conductive layer stacked with the first semiconductor layer pattern. In some exemplary implementations, as shown in FIG. 15B, the first conductive layer pattern includes at least: a first scanning signal line Gate_P, a reset control signal line Reset_P, a light-emitting control signal line EM_P, and a first capacitor electrode Ce1 of the storage capacitor. In some exemplary implementations, the first conductive layer may be referred to as a first gate metal (GATE 1) layer.

In some exemplary implementations, in the first direction, the first conductive layers of any two adjacent columns of sub-pixels are mirror symmetric structures.

In some exemplary implementations, the first scanning signal line Gate_P, the reset control signal line Reset_P, and the light-emitting control signal line EM_P are all along the second direction. Within each sub-pixel, the reset control signal line Reset_P is located on a side of the first scanning signal line Gate_P away from the light-emitting control signal line EM_P, the first capacitor electrode Ce1 of the storage capacitor is disposed between the first scanning signal line Gate_P and the light-emitting control signal line EM_P.

In some exemplary implementations, the first capacitor electrode Ce1 may have a rectangular shape, corners of the rectangular shape may be provided with chamfers, and there is an overlapping region of an orthographic projection of the first capacitor electrode Ce1 on the base substrate and an orthographic projection of the third active layer 30 of the third transistor T3 on the base substrate. In some exemplary implementations, the first capacitor electrode Ce1 also serves as the gate electrode of the third transistor T3, and a region where the third active layer 30 of the third transistor T3 overlaps with the first capacitor electrode Ce1 serves as the channel region of the third transistor T3, and one end of the channel region is connected to the first region of the third active layer 30 and the other end is connected to the second region of the third active layer 30.

In some exemplary implementations, a region of the reset control signal line Reset P where the reset control signal line Reset_P overlaps with the first active layer of the first transistor T1 serves as the gate electrode of the first transistor T1, a region of the first scanning signal line Gate_P where the first scanning signal line Gate_P overlaps with the second active layer of the second transistor T2 serves as the gate electrode of the second transistor T2, a region of the first scanning signal line Gate_P where the first scanning signal line Gate_P overlaps with the fourth active layer of the fourth transistor T4 serves as the gate electrode of the fourth transistor T4, a region of the light-emitting control signal line EM_P where the light-emitting control signal line EM_P overlaps with the fifth active layer of the fifth transistor T5 serves as the gate electrode of the fifth transistor T5, and a region of the light-emitting control signal line EM_P where the light-emitting control signal line EM_P overlaps with the sixth active layer of the sixth transistor T6 serves as the gate electrode of the sixth transistor T6. A region of the reset control signal line Reset_P in the next row of sub-pixels of each row of sub-pixels where the reset control signal line Reset P in the next row (the signal of which is the same as the first scanning signal line Gate_P in the present row of sub-pixels) overlaps with the seventh active layer of the seventh transistor T7 in the present row of sub-pixels serves as the gate electrode of the seventh transistor T7.

In the manufacturing process of the display panel, after forming the pattern of the first conductive layer, the first semiconductor layer may be subjected to an electrical conduction process using the first conductive layer as a shield, the first semiconductor layer in a region shielded by the first conductive layer forms the channel region of each transistor, and the first semiconductor layer in a region not shielded by the first conductive layer is conductive, i.e., both the first region and the second region of each active layer are conductive.

FIG. 15C shows a schematic plan view of a second conductive layer pattern stacked on the basis of FIG. 15B. In some exemplary implementations, as shown in FIG. 15C, the second conductive layer pattern includes at least: the second capacitor electrode Ce2 of the storage capacitor and the first branch GateN_B1 of the second scanning signal line GateN. In some exemplary implementations, the second conductive layer may be referred to as a second gate metal (GATE 2) layer.

In some exemplary implementations, in the first direction, the second conductive layers of any two adjacent columns of sub-pixels are mirror symmetric structures.

In some exemplary implementations, the first branch GateN_B1 of the second scanning signal line GateN extends in the second direction. Within each sub-pixel, the second capacitor electrode Ce2 of the storage capacitor is located between the first branch GateN_B1 of the second scanning signal line GateN and the light-emitting control signal line EM_P.

In some exemplary implementations, the profile of the second capacitor electrode Ce2 may have a rectangular shape, the corners of the rectangular shape may be chamfered, and there is an overlapping region of an orthographic projection of the second capacitor electrode Ce2 on the base substrate and an orthographic projection of the first capacitor electrode Ce1 on the base substrate. The second capacitor electrode Ce2 is provided with an opening H, which may be located in the middle of the second capacitor electrode Ce2. The opening H may be in a regular hexagon shape, so that the second capacitor electrode Ce2 forms an annular structure. In some example implementations, the opening H is configured to receive a subsequently formed fourth via, the fourth via is provided within the opening H and exposes the first capacitor electrode Ce1, thereby facilitating the connecting of the subsequently formed source-drain electrode of the eighth transistor T8 with the first capacitor electrode Ce1.

FIG. 15D shows a schematic plan view of a second semiconductor layer pattern stacked on the basis of FIG. 15C. In some exemplary implementations, as shown in FIG. 15D, the second semiconductor layer of each sub-pixel may include an eighth active layer 80 of an eighth transistor T8. In some exemplary implementations, the eighth active layer 80 extends along the first direction, the shape of the eighth active layer 80 may be dumbbell-shaped. In the first direction, the second semiconductor layers of any two adjacent columns of sub-pixels are in mirror symmetric structures.

In some exemplary implementations, the first region 801 of the eighth active layer 80 is close to the first active layer of the first transistor T1, and the second region 802 of the eighth active layer 80 is close to the first capacitor C1.

In some exemplary implementations, the second semiconductor layer may adopt an oxide, i.e., the eighth transistor is an oxide thin film transistor.

FIG. 15E shows a schematic plan view of a third conductive layer pattern stacked on the basis of FIG. 15D. In some exemplary implementations, as shown in FIG. 15E, the third conductive layer pattern includes at least: a second branch GateN_B2 of the second scanning signal line GateN and a second initial signal line INIT2. In some exemplary implementations, the third conductive layer may be referred to as a third gate metal (GATE3) layer.

In some exemplary implementations, in the first direction, the third conductive layers of any two adjacent columns of sub-pixels are mirror symmetric structures.

In some exemplary implementations, the second branch GateN_B2 of the second scanning signal line GateN extends along the second direction, the second branch GateN_B2 of the second scanning signal line GateN is close to the second branch Gate_B2 of the first scanning signal line Gate. In some exemplary implementations, a region of the second branch GateN_B2 where the second branch GateN_B2 of the second scanning signal line GateN overlaps with the eighth active layer 80 serves as the gate electrode of the eighth transistor.

In some example implementations, an orthographic projection of the second branch GateN_B2 of the second scanning signal line on the base substrate overlaps with an orthographic projection of the first branch GateN_B1 of the second scanning signal line on the base substrate. In some exemplary implementations, the first branch GateN_B1 of the second scanning signal line and the second branch GateN_B2 of the second scanning signal line may be connected through a signal line in the peripheral region.

In some exemplary implementations, the second initial signal line INIT2 extends along the second direction, within each row of sub-pixels, the second initial signal line INIT2 is disposed on a side of the reset control signal line Reset_P away from the first scanning signal line Gate_P.

FIG. 15F shows a schematic plan view of a plurality of vias formed on the basis of FIG. 15E. In some exemplary implementations, insulating layers are formed on the pattern of FIG. 15E and between adjacent conductive layers, the insulating layers have a plurality of vias therein, including at least: a first via V1, a second via V2, a third via V3, a fourth via V4, a fifth via V5, a sixth via V6, a seventh via V7, an eighth via V8, a ninth via V9, a tenth via V10, and an eleventh via V11.

In some exemplary implementations, the first via V1 exposes a surface of the second region of the eighth active layer 80. The second via V2 exposes a surface of the first region of the eighth active layer 80. The third via V3 exposes a surface of the first region of the second active layer (which is also the second region of the first active layer). The third via V3 is configured such that a subsequently formed first electrode of the second transistor T2 is connected with the second active layer through the third via, and a subsequently formed second electrode of the first transistor T1 is connected with the first active layer through the third via.

In some exemplary implementations, the fourth via V4 is located within the opening H of the second capacitor electrode Ce2, an orthographic projection of the fourth via V4 on the base substrate is within a range of an orthographic projection of the opening H on the base substrate, and the fourth via V4 exposes a surface of the first capacitor electrode Ce1. The fourth via V4 is configured such that the subsequently formed third connection electrode 43 is connected with the first capacitor electrode Ce1 through the fourth via.

In some exemplary implementations, the fifth via V5 exposes a surface of the first region of the fifth active layer. The fifth via V5 is configured such that the subsequently formed first electrode of the fifth transistor T5 is connected to the fifth active layer through the fifth via.

In some exemplary implementations, the sixth via V6 is located in a region where the second capacitor electrode Ce2 is located, an orthographic projection of the sixth via V6 on the base substrate is within a range of an orthographic projection of the second capacitor electrode Ce2 on the base substrate, and the sixth via V6 exposes the surface of the second capacitor electrode Ce2. The sixth via V6 is configured such that a subsequently formed fifth connection electrode 45 is connected with the second capacitor electrode Ce2 through the sixth via.

In some exemplary implementations, the seventh via V7 exposes a surface of the first region of the first active layer. The seventh via V7 is configured such that a subsequently formed first electrode of the first transistor T1 is connected with the first active layer through the seventh via.

In some exemplary implementations, the eighth via V8 exposes a surface of the first region of the seventh active layer. The eighth via V8 is configured such that a subsequently formed first initial signal line is connected with the seventh active layer through the eighth via.

In some exemplary implementations, the ninth via V9 exposes a surface of the second region of the sixth active layer (which is also the second region of the seventh active layer). The ninth via V9 is configured such that a subsequently formed second electrode of the sixth transistor T6 is connected with the sixth active layer through the ninth via, and a subsequently formed second electrode of the seventh transistor T7 is connected with the seventh active layer through the ninth via.

In some exemplary implementations, the tenth via V10 exposes a surface of the first region of the fourth active layer. The tenth via V10 is configured such that a subsequently formed second connection electrode 42 is connected with the fourth active layer through the tenth via.

In some exemplary implementations, the eleventh via V11 exposes a surface of the second initial signal line INIT2. The eleventh via V11 is configured such that a subsequently formed sixth connection electrode 46 is connected with the second initial signal line INIT2 through the eleventh via.

FIG. 15G shows a schematic plan view of a fourth conductive layer pattern stacked on the basis of FIG. 15F. As shown in FIG. 15G, the fourth conductive layer includes at least: a first initial signal line INIT1, a first connection electrode 41, a second connection electrode 42, a third connection electrode 43, a fourth connection electrode 44, a fifth connection electrode 45, and a sixth connection electrode 46. In some exemplary implementations, the fourth conductive layer may be referred to as a first source-drain metal (SD1) layer.

In some exemplary implementations, in the first direction, the fourth conductive layers of any two adjacent columns of sub-pixels are mirror symmetric structures.

In some exemplary implementations, the first initial signal line INIT1 extends along the second direction, the first initial signal line INIT1 is connected with the first region of the seventh active layer through the eighth via V8, so that the first electrode of the seventh transistor T7 has the same potential as the first initial signal line INIT1.

In some exemplary implementations, one end of the first connection electrode 41 is connected with the first region of the second active layer (also the second region of the first active layer) through the third via V3, and the other end of the first connection electrode 41 is connected with the first region of the eighth active layer through the second via V2. In some exemplary implementations, the first connection electrode 41 may serve as a first electrode of the eighth transistor T8, a first electrode of the second transistor, and a second electrode of the first transistor.

In some exemplary implementations, the second connection electrode 42 is connected with the first region of the fourth active layer through the tenth via V10 on the one hand, and connected with a subsequently formed data signal line Data through a subsequently formed thirteenth via V13 on the other hand. In some exemplary implementations, the second connection electrode 42 may serve as a first electrode of the fourth transistor T4

In some exemplary implementations, one end of the third connection electrode 43 is connected with the second region of the eighth active layer through the first via V1, and the other end of the third connection electrode 43 is connected with the first capacitor electrode Ce1 through the fourth via V4. In some exemplary implementations, the third connection electrode 43 may serve as the second electrode of the eighth transistor T8.

In some exemplary implementations, the fourth connection electrode 44 is connected with the second region of the sixth active layer (which is also the second region of the seventh active layer) through the ninth via V9 on the one hand, and connected with a subsequently formed anode connection electrode through a subsequently formed twelfth via V12 on the other hand. In some exemplary implementations, the fourth connection electrode 44 may serve as the second electrode of the sixth transistor T6 and the second electrode of the seventh transistor T7 at the same time.

In some exemplary implementations, the fifth connection electrode 45 (power connection electrode) is connected to the second capacitor electrode Ce2 through the sixth via V6 on the one hand, and connected to the first region of the fifth active layer through the fifth via V5 on the other hand, the fifth connection electrode 45 is configured to be connected to a subsequently formed first power line VDD through a subsequently formed fourteenth via V14.

In some exemplary implementations, one end of the sixth connection electrode 46 is connected with the first region of the first active layer through the seventh via V7, and the other end of the sixth connection electrode 46 is connected with the second initial signal line through the eleventh via V11, so that the first electrode of the first transistor T1 has the same potential as the second initial signal line INIT2.

FIG. 15H shows a schematic plan view of a first planarization layer and a fifth conductive layer pattern stacked on the basis of FIG. 15G. As shown in FIG. 15H, the first planarization layer includes at least: a twelfth via V12, a thirteenth via V13, and a fourteenth via V14, and the fifth conductive layer includes at least: a data signal line Data, a first power line VDD, and an anode connection electrode 51. In some exemplary implementations, the fifth conductive layer may be referred to as a second source-drain metal (SD2) layer, which is also the first metal layer in the embodiments of the present disclosure, and the data signal line Data is the above-described data line DT.

In some exemplary implementations, in the first direction, the fifth conductive layers of any two adjacent columns of sub-pixels are mirror symmetric structures. In other exemplary implementations, in the first direction, the fifth conductive layers of any adjacent two columns of sub-pixels may also not be the mirror symmetric structures, the area of the second source-drain metal layer below the second opening or the third opening may be increased as necessary to increase the flatness of the anode formed in the upper layer, so that the sub-pixels are located on one plane as a whole, the color cast can be reduced, and the display quality can be improved.

In some exemplary implementations, as shown in FIG. 15H, within one repeating unit, the first power lines VDD in the adjacent two columns of sub-pixels may be connected with each other to form an integral structure. By forming the first power lines VDD in the adjacent two columns of sub-pixels into an integrated structure, the anodes formed in the upper layer can be made flatter.

In some exemplary implementations, the anode connection electrode 51 may have a rectangular shape, and the anode connection electrode 51 is connected with the fourth connection electrode 44 through the twelfth via V12.

In some exemplary implementations, the first power line VDD is connected with the fifth connection electrode 45 through the fourteenth via V14.

In some exemplary implementations, the data signal line Data extends along the first direction, the data signal line Data is connected with the second connection electrode 42 through the thirteenth via V13, because the second connection electrode 42 is connected with the first region of the fourth active layer through the tenth via V10, the data signal line is connected with the first electrode of the fourth transistor, so that the data signal transmitted by the data signal line Data can be written into the fourth transistor.

FIG. 15I shows a schematic plan view of a second planarization layer pattern stacked on the basis of FIG. 15H. As shown in FIG. 15I, at least a fifteenth via V15 is provided in the second planarization layer.

In some exemplary implementations, the fifteenth via V15 is located in the region where the anode connection electrode 51 is located, the second planarization layer in the fifteenth via V15 is removed to expose a surface of the anode connection electrode 51, and the fifteenth via V15 is configured to allow a subsequently formed anode to be connected to the anode connection electrode 51 through the fifteenth via.

For example, on the basis of FIG. 15I, a sixth conductive layer pattern may also be stacked, which is also the second metal layer in the embodiments of the present disclosure. The sixth conductive layer pattern includes the plurality of first signal lines L1 described above, and specifically, reference can be made to FIGS. 6-8, which are not repeated here.

For example, the sixth conductive layer pattern is stacked with a first electrode (anode) pattern. In some exemplary implementations, the anode is connected with the anode connection electrode 51 through the fifteenth via V15. Because the anode connection electrode 51 is connected with the fourth connection electrode 44 through the twelfth via V12, and the fourth connection electrode 44 is also connected with the second region of the sixth active layer (which is also the second region of the seventh active layer) through the ninth via V9, it is realized that the pixel circuit can drive the light-emitting device to emit light.

Other functional layers such as a light-emitting material layer, a second electrode layer, and an encapsulation layer are included on the display panel, and are not repeated here.

At least one embodiment of the present disclosure provides a display device, the display device includes the any one of the above display substrates. For example, the display device may be any product or component having a display function, such as a phone, a tablet computer, a television, a monitor, a notebook computer, a digital photo frame, a navigator, or the like.

The following statements should be noted:
(1) The drawings involve only the structure(s) in connection with the embodiment(s) of the present disclosure, and other structure(s) can be referred to common design(s).
(2) For clarity, in the drawings used to describe the embodiments of the present disclosure, the thicknesses of layers or regions are enlarged or reduced, that is, the drawings are not drawn to actual scale. It can be understood that when a component such as a layer, film, region or substrate is referred to as being “on” or “under” another component, the component may be “directly” “on” or “under” another component, or one or more intermediate components may be interposed therebetween.
(3) In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

Listing of claims:

1. A display substrate, having a display region, wherein the display region comprises:
a base substrate,
a plurality of sub-pixels on the base substrate, wherein each of at least part of the plurality of sub-pixels comprises a pixel driving circuit and a light-emitting device, the light-emitting device comprises a first electrode electrically connected to the pixel driving circuit,
a plurality of data lines on the base substrate and in a first metal layer, and
a plurality of first signal lines on the base substrate and in a second metal layer, wherein the second metal layer is on a side of the first metal layer away from the base substrate, at least one of the plurality of first signal lines is electrically connected to at least one of the plurality of data lines through a first via;
wherein the display region comprises a first display region, in the first display region, the plurality of first signal lines extend in a first direction, the first display region comprises a plurality of first compensation patterns,
in the first display region, first electrodes of light-emitting devices of the plurality of sub-pixels are on a side of the plurality of first signal lines and the plurality of first compensation patterns away from the base substrate, an orthographic projection of at least one of the plurality of first compensation patterns on the base substrate at least partially overlaps with an orthographic projection of the first electrode of the light-emitting device of at least one of the plurality of sub-pixels on the base substrate.

2. The display substrate according to claim 1, wherein the plurality of first compensation patterns are in the second metal layer.

3. The display substrate according to claim 1, wherein the display region further comprises a second display region, in the second display region, the plurality of first signal lines extend in a second direction, the second display region comprises a second compensation pattern,
in the second display region, first electrodes of light-emitting devices of the plurality of sub-pixels are on a side of the plurality of first signal lines and the plurality of second compensation patterns away from the base substrate, an orthographic projection of at least one of the plurality of second compensation patterns on the base substrate at least partially overlaps with an orthographic projection of the first electrode of the light-emitting device of at least one of the plurality of sub-pixels on the base substrate;
the first direction is different from the second direction.

4. (canceled)

5. The display substrate according to claim 3, wherein the plurality of first signal lines are electrically connected to the plurality of data lines through a plurality of first vias, respectively, the plurality of first vias are in the second display region and arranged in a straight line, the straight line intersects the first direction and the second direction.

6. (canceled)

7. The display substrate according to claim 3, wherein in the second display region, the plurality of first signal lines extend in the second direction to an edge of the display region and are disconnected on a side of the plurality of first vias close to the edge.

8. The display substrate according to claim 7, wherein portions of the plurality of first signal lines disconnected on the side of the plurality of first vias close to the edge are electrically connected with the plurality of data lines, respectively.

9. The display substrate according to claim 1, wherein the pixel driving circuit and the first electrode are electrically connected through a second via, in a direction perpendicular to the base substrate, the second via does not overlap with the first via.

10. The display substrate according to claim 3, wherein the plurality of first compensation patterns and the plurality of second compensation patterns are respectively in a shape of Chinese character “ [symbol] ”, a shape of Chinese character “ [symbol] ”, a shape of Chinese character “ [symbol] ”, a shape of Chinese character “ [symbol] ”, a shape of a ring or a shape of a block.

11. (canceled)

12. The display substrate according to claim 3, wherein in the first display region, the plurality of first compensation patterns comprise first compensation patterns electrically connected with the plurality of first signal lines, respectively, and respectively in a shape of Chinese character “ [symbol] ” extending in the second direction.

13. The display substrate according to claim 12, wherein the plurality of sub-pixels comprise red sub-pixels, green sub-pixels, and blue sub-pixels,
light-emitting devices of the red sub-pixels and the blue sub-pixels are in a same row, and light-emitting devices of the green sub-pixels are in a same row, and rows where the light-emitting devices of the red sub-pixels and the blue sub-pixels are located and rows where the light-emitting devices of the green sub-pixels are located are alternately arranged;
the light-emitting devices of the red sub-pixels and the blue sub-pixels are in a same column, the light-emitting devices of the green sub-pixels are in a same column, and columns where the light-emitting devices of the red sub-pixels and the blue sub-pixels are located and columns where the light-emitting devices of the green sub-pixels are located are alternately arranged.

14. The display substrate of claim 13, wherein in the first display region and in the direction perpendicular to the base substrate, the first signal line at least partially overlaps with the light-emitting device of the green sub-pixel, and the first signal line does not overlap with the light-emitting devices of the red sub-pixel and the blue sub-pixel.

15. The display substrate according to claim 14, wherein in the first display region and in the direction perpendicular to the base substrate, a first electrode of a light-emitting device of the green sub-pixel at least partially overlaps the first compensation pattern in the shape of Chinese character “ [symbol] ”.

16. The display substrate according to claim 14, wherein the plurality of first compensation patterns further comprise a first compensation pattern in a shape of Chinese character “ [symbol] ” on at least one side of the plurality of first signal lines, the first compensation pattern in the shape of Chinese character “ [symbol] ” comprises two portions respectively extending along the first direction and the second direction.

17. The display substrate according to claim 16, wherein the first compensation pattern in the shape of Chinese character “ [symbol] ” is spaced apart from the plurality of first signal lines.

18. The display substrate according to claim 16, wherein in the direction perpendicular to the base substrate, the first electrodes of the light-emitting devices of the red sub-pixel and the blue sub-pixel respectively overlap with one first compensation pattern in the shape of Chinese character “ [symbol] ”.

19. The display substrate according to claim 13, wherein in the second display region, the plurality of second compensation patterns comprise a second compensation pattern in a shape of Chinese character “ [symbol] ” on at least one side of the plurality of first signal lines, the second compensation pattern in the shape of Chinese character “ [symbol] ” comprises two portions respectively extending along the first direction and the second direction;
in the direction perpendicular to the base substrate, first electrodes of light-emitting devices of the green sub-pixel, the red sub-pixel and the blue sub-pixel respectively overlap with one second compensation pattern in the shape of Chinese character “ [symbol] ”.

20. The display substrate according to claim 3, wherein the light-emitting device further comprises a light-emitting material layer on a side of the first electrode away from the base substrate and a second electrode on a side of the light-emitting material layer away from the base substrate;
the display substrate further has a peripheral region surrounding the display region,
the display substrate further comprises a first power signal line configured to provide a first power signal to second electrodes of the plurality of sub-pixels, and the first power signal line is electrically connected, in the peripheral region, to the second electrodes of the plurality of sub-pixels.

21. The display substrate according to claim 20, wherein in the second display region, the second compensation pattern in the shape of Chinese character “ [symbol] ” is electrically connected with the first power signal line.

22. The display substrate according to claim 20, further comprising a second power signal line, wherein the plurality of first signal lines are on a side of the second power signal line away from the base substrate, the second compensation pattern in the shape of Chinese character “ [symbol] ” is electrically connected to the second power signal line.

23. The display substrate according to claim 1, wherein the display region further comprises a third display region, the third display region comprises a metal pattern, first electrodes of light-emitting devices of the plurality of sub-pixels are on a side of the metal pattern away from the base substrate,
the metal pattern comprises a plurality of metal lines extending at least along the first direction and the second direction and crossing with each other; or, the metal pattern comprises a plurality of block patterns respectively overlapping with the first electrodes of the light-emitting devices of at least part of the plurality of sub-pixels.

24-26. (canceled)
